(19) United States
(12) Patent Application Publication
(10) Pub. No.: US 2017/0099888 A1
(43) Pub. Date: Apr. 13, 2017

(54) ELECTRICAL SAFETY DEVICE

(71) Applicant: Kevin James Flynn, Janesville, WI (US)

(72) Inventor: Kevin James Flynn, Janesville, WI (US)

(21) Appl. No.: 15/252,752

(22) Filed: Aug. 31, 2016

Related U.S. Application Data
(60) Provisional application No. 62/240,049, filed on Oct. 12, 2015.

(51) Int. Cl. A41D 19/00; G01R 19/145; G08B 21/02

(52) U.S. Cl. CPC A41D 19/0031; A41D 19/0027; G08B 21/02; G01R 19/145

(57) ABSTRACT

An electrical safety device adapted to be worn by a human user is provided. electrical safety device may take the form of a glove, wherein the electrical safety device continuously monitors for and alerts the user of the presence of predetermined levels of electric current and voltage differentials before contact is made, obviating human error and the necessity of carrying additional tools when working around electrical devices.

### BACKGROUND OF THE INVENTION

The present invention relates to electrical safety device and, more particularly, an electrical safety glove adapted for a human wearer wherein the electrical safety glove continuously monitors for and alerts the wearer of live electrical current and voltage differentials before the wearer contacts such dangers.

The human body does not deal well with live electrical contact, and so workers who regularly encounter energized circuits need to take appropriate precautions against electrocution. Typically, such circuits' electrical hazard cannot be visually determined, and so during the course of the workday human error or complacency can lead such workers to contact an energized circuit. For example, when performing a task involving electrical devices, such worker's hand may be in the electrical device, such as an electrical panel, and if the power is suddenly restored, the worker may not have immediate knowledge of it.

Non-contact current voltage detection equipment requires an additional tool and additional action to scan for electricity, as the tool has to be pulled out and used, and then thereafter properly put away to resume the task at hand. This additional action is itself susceptible to human error.

As can be seen, there is a need for an electrical safety glove adapted for a human wearer, wherein the electrical safety glove continuously monitors for and alerts the wearer of live electrical current and voltage differentials before contact is made, preventing human error and the necessity of carrying additional tools.

### SUMMARY OF THE INVENTION

In one aspect of the present invention, a

In another aspect of the present invention, the

These and other features, aspects and advantages of the present invention will become better understood with reference to the following drawings, description and claims.

### BRIEF DESCRIPTION OF THE DRAWINGS

FIG. 1 is a perspective view of an exemplary embodiment of the present invention, shown in use;

FIG. 2 is a perspective view of an exemplary embodiment of the present invention, shown in use;

FIG. 3 is a detailed perspective view of an exemplary embodiment of the present invention;

FIG. 4 is a schematic view of an exemplary embodiment of the present invention;

FIG. 5 is a top plan view of an exemplary embodiment of the present invention; and

FIG. 6 is a side elevational view of an exemplary embodiment of the present invention.

### DETAILED DESCRIPTION OF THE INVENTION

The following detailed description is of the best currently contemplated modes of carrying out exemplary embodiments of the invention. The description is not to be taken in a limiting sense, but is made merely for the purpose of illustrating the general principles of the invention, since the scope of the invention is best defined by the appended claims.

Broadly, an embodiment of the present invention provides an electrical safety device adapted to be worn by a human user, wherein the electrical safety device continuously monitors for and alerts the user of the presence of predetermined levels of electric current and voltage differentials before contact is made, obviating human error and the necessity of carrying additional tools when working around electrical devices.

The electrical safety device may include an input device for making non-contact determinations of voltage differentials between the user and a plurality of electrical sensors disposed along the input device. A control circuitry is adapted to activate the visual output device when a predetermined voltage differential is determined by the plurality of electrical sensors between a nearby live electrical contact and the user. In certain embodiments, the electrical safety device may be a glove adapted for a human wearer.

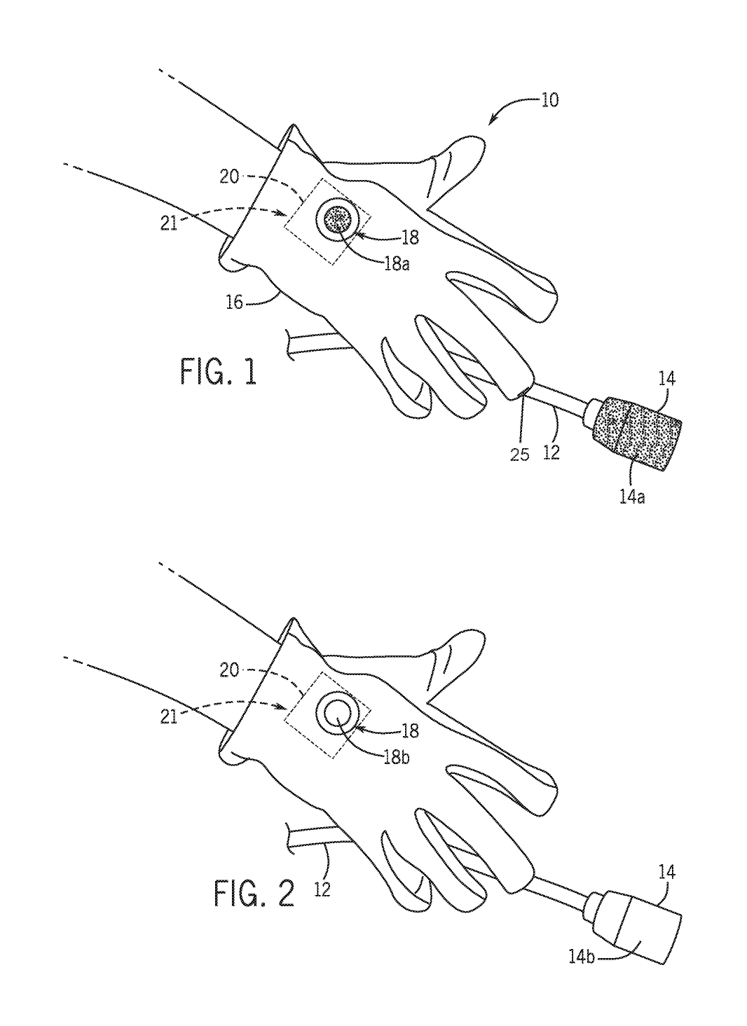

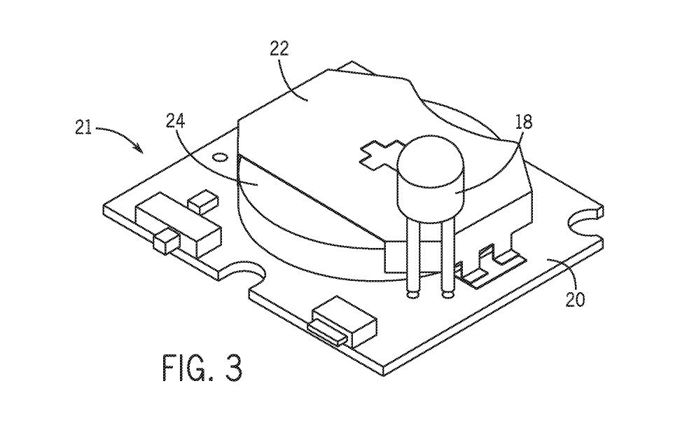

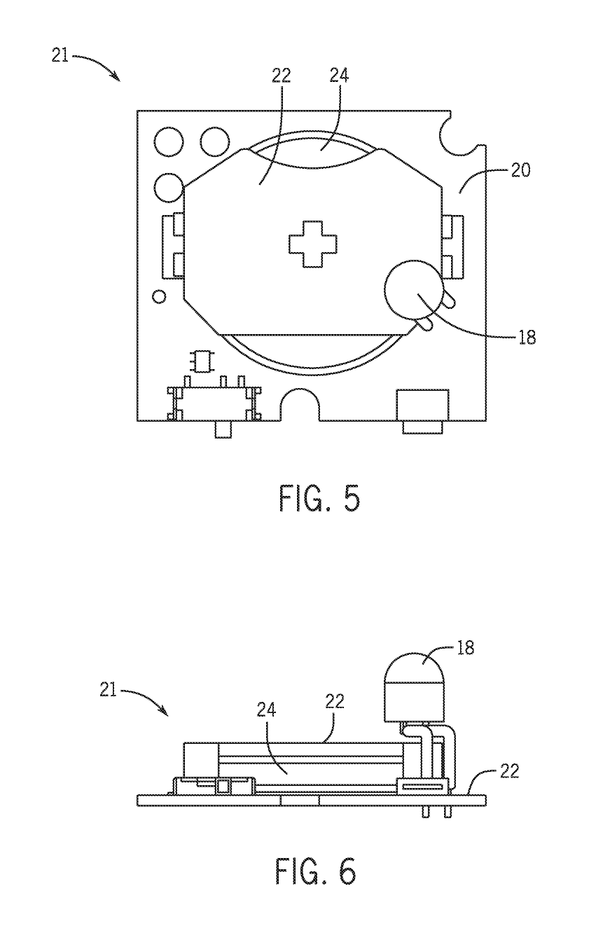

Referring to FIGS. 1 through 6, the present invention may include an electrical safety device 10 adapted to be worn by a human user, wherein the electrical safety device 10 continuously monitors for and alerts the user regarding live electrical contact, removing human error and the necessity of carrying additional tools. The electrical safety device 10 may provide an input device/detection system 21 coupling a control circuitry 20, a visual output device 18, a power source 24, and at least one electrical sensor 25. The control circuitry 20 may be a printed circuit board or the like. The coupled visual output device 18 may be a LED or the like. Each electrical sensor 25 may be adapted to sense, without physical contact, an electrical current and/or a voltage over a predetermined threshold. The input device 21 may physically combine the visual output device 18, control circuitry 20, and the power source 24, including a battery holder 24 for said power source 22, as illustrated in FIG. 3. In this embodiment, the visual output device 18 may be applied with an insulating sleeve, keeping the visual output devices 18 from shortening the power source 24. In other embodiments, the components of the input device/detection system 21 may be physically separated, but electrically coupled remotely or through wiring.

The control circuitry 20 may be inserted inside a protective housing. The protective housing may be made of durable, easy to form material, such as plasticized materials, polycarbonates, or the like.

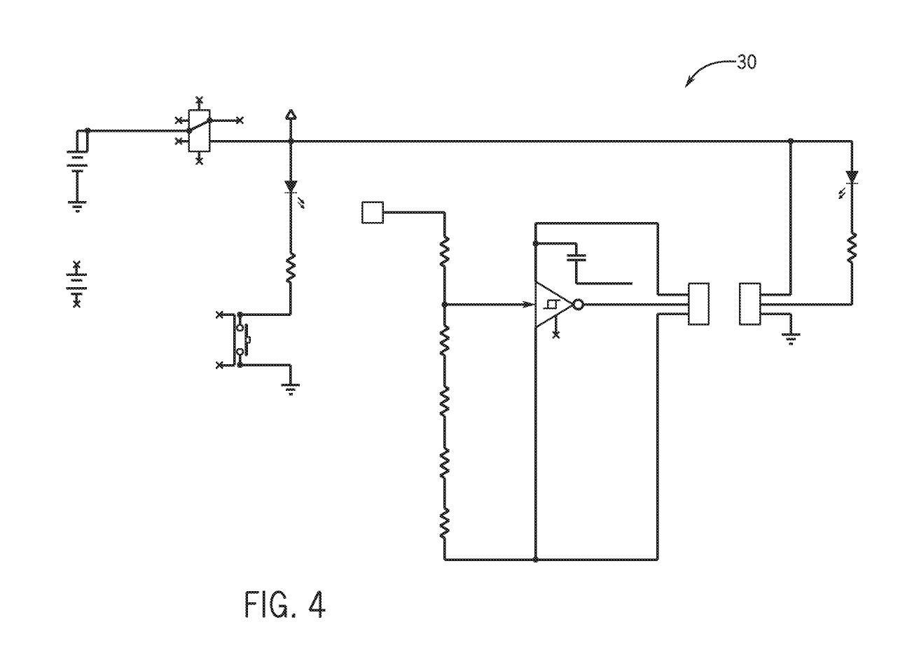

The input device/detection system 21 may be embedded in or attached to the electrical safety device 10. In certain embodiments, the electrical safety device 10 may be a glove 16 that is adapted for a human wearer. In such an embodiment, the input device/detection system 21 may be embedded near the back portion of the glove 16, for example, near a wearer's wrist, as illustrated in FIGS. 1 and 2. The electrical safety glove 16 (in this particular embodiment) may provide the at least one electrical sensor 25 along an exterior surface of the electrical safety glove 16, so that each electrical sensor 25 may be adapted to determine and convey electrical current and/or voltage differentials detection of nearby electrical sources/signals prior to physical contact. For example, each electrical sensor 25 may be disposed at or near the distal fingertip portion of the electrical safety glove 16, wherein each electrical sensor 25 may provide a surface area that is conductive and receptive to an ionic field generated by live electrical current in a conductor. The electrical sensors 25 are coupled to the control circuitry 20, wherein the control circuitry 20 may be adapted so that when a predetermined voltage differential between at least one of the electrical sensors 25 and the control circuit 20 is determined, the visual output device 18 is activated. An exemplary schematic embodiment of the control circuit 20 is illustrated in FIG. 4.

In certain embodiments, the electrical safety glove 10 may include a second detection board, plurality of electrical sensors and a base electrical sensor electronically connected to the control circuitry 20, electronically coupled remotely or by wiring. The base electrical sensor may be adapted to sense ground through the human wearer. The control circuitry 20 may be adapted so that when a predetermined voltage differential between at least one of the plurality of electrical sensors 25 and the base electrical sensor is determined, the visual output device 18 is activated.

A method of using the present invention may include the following. The electrical safety glove 16 disclosed above may be provided. A user may turn the input device/detection system 21 on, testing the visual output devices 18 by donning the electrical safety glove 16 then passing the electrical safety glove 16 near and/or adjacent to (but not touching) a known live electrical source 14a—i.e., near electrical devices 12 and 14—to ensure the visual output device 18 properly activates 18a, as illustrated in FIG. 1. Similarly, the wear would pass the electrical safety glove 16 near and/or adjacent to (but not touching) a known “dead” electrical source 14b to ensure the visual output device 18 does not activate 18b, as illustrated in FIG. 2. Then the user, wearing the electrical safety glove 16, may set out to complete a task where there is a chance of contact with live electrical sources 14a.

Though gloves have the additional utility of protecting against cuts to the wearer's hand, the input device/detection system 21 could be attached to other tools, as well as pre-existing pairs of gloves.

It should be understood, of course, that the foregoing relates to exemplary embodiments of the invention and that modifications may be made without departing from the spirit and scope of the invention as set forth in the following claims.

What is claimed is:

1. An electrical safety device, comprising:
an input device providing a control circuitry coupled to at least one electrical sensor;
the input device adapted to be worn by a human user;
a base electrical sensor coupled to the control circuitry, wherein the base electrical sensor is configured to establish the human user as ground;
at least one visual output device coupled to the control circuit; and
the control circuitry configured to activate the at least one visual output device if a predetermined voltage determination is made between one of the at least one electrical sensor and the base electrical sensor.

2. The electrical safety device of claim 1 for use with a glove, further comprising a glove to which the input device is attached.

3. The electrical safety device of claim 2, wherein each of the at least one electrical sensor provides a surface area disposed on a distal fingertip portion of the glove.

4. The electrical safety device of claim 3, wherein the predetermined voltage determination is defined as a voltage sufficient to injure the human user.

5. The electrical safety device of claim 4, wherein the predetermined voltage determination is made without any of the at least one electrical sensor physically touching a voltage source of the predetermined voltage determination.

6. An electrical safety device, comprising:
an input device providing a control circuitry coupled to at least one electrical sensor;
the input device adapted to be worn by a human user;
at least one visual output device coupled to the control circuit; and
the control circuitry configured to activate the at least one visual output device if a predetermined voltage determination is made between one of the at least one electrical sensor and a voltage source said one of the at least one electrical sensor is adjacent to and spaced apart from.

7. The electrical safety device of claim 6 for use with a glove, further comprising a glove to which the input device is attached.

8. The electrical safety device of claim 7, wherein each of the at least one electrical sensor provides a surface area disposed on a distal fingertip portion of the glove.

9. The electrical safety device of claim 8, wherein the predetermined voltage determination is defined as a voltage sufficient to injure the human user.

10. A method of preventing electrocution of a human user's hand, comprising the steps of:
donning the electrical safety device of claim 8 on the human user's hand; and
disposing said human user's hand adjacent to and spaced apart from an electrical device.
